(19) United States
(12) Patent Application Publication
(10) Pub. No.: US 2010/0141484 A1
(43) Pub. Date: Jun. 10, 2010

(54) OPTIMIZED KEYBOARD FOR HANDHELD THUMB-TYPING AND TOUCH-TYPING

(75) Inventors: Jason T. Griffin, Kitchener (CA); Norman M. Ladouceur, Waterloo (CA); Roman P. Rak, Waterloo (CA); Steven Fyke, Waterloo (CA)

Correspondence Address: RIM, 1000 LOUISIANA STREET, FIFTY-THIRD FLOOR, HOUSTON, TX, 77002, US

(73) Assignee: RESEARCH IN MOTION LIMITED, Waterloo (CA)

(21) Appl. No.: 12/330,298

(22) Filed: Dec. 8, 2008

(51) Int. Cl. H03K 17/94

(52) U.S. Cl. 341/22

(57) ABSTRACT

A keyboard optimized for handheld thumb-typing and conventional desktop touch-typing includes a reduced key keyboard having a plurality of keys each having at least an alphabetic character, a numeral, or a command indicia. The keyboard has a width greater than about 100 millimeters and less than about 160 millimeters, and each key has a width that is approximately 10 millimeters to 16 millimeters. The alphabetic keys are arranged such that when a user cradles the device in his/her hands he/she can actuate a first subset of the keys on the left of a vertical center line with his/her left thumb and can actuate a second subset of the keys on the right side of the vertical centerline with his/her right thumb. The keys are also positioned such that when the user places the device on a desktop surface, the user can type on the keyboard by conventional finger touch-typing.

### FIELD OF TECHNOLOGY

The present disclosure relates generally to keyboards. More specifically, the present disclosure relates to optimized keyboards for handheld thumb-typing and touch-typing on a device.

### BACKGROUND

With the advent of more robust handheld electronic systems, advancements of handheld electronic devices are becoming more prevalent. Handheld electronic devices can provide a variety of functions including, for example, telephonic, electronic messaging and other personal information manager (PIM) application functions. Handheld electronic devices include mobile stations such as simple cellular telephones, smart telephones, wireless PDAs, and reduced-sized laptop computers.

Such handheld devices allow the user to enter data into text messages, email messages, address books, calendars, task lists, and other similar text files. To facilitate text entry, prior handheld electronic devices have provided the user with a keypad having a minimal number of keys, but with keys representing the alphabet generally placed in the same order as they would appear on a standard keyboard, such as in the QWERTY keyboard layout. The use of a keyboard layout that is familiar to the user enables the user to immediately use the device without having to hunt for the keys he wishes to use. However, such devices provide keyboards that are designed to be used substantially by the user's thumbs. While this keyboard configuration is more accurate and faster to use than “hunt and peck” typing, it is not optimized for both thumb-typing and conventional finger typing (i.e. touch-typing). Furthermore, handheld devices having keyboards configured for thumb-typing are often too small to be used for touch-typing as well. These devices are to be used while the device is cradled in the user's hands rather than while the user places the device on a desktop for conventional finger-typing. If one were to perform touch-typing on a keyboard optimized for only thumb-typing, the user's hands might feel discomfort because the keys are either too small or spaced together too closely for comfortable touch-typing. Also, because of the smaller keyboard and smaller space between the keys, touch-typing on a keyboard optimized for thumb-typing results in increased typing errors and user frustration.

On the other hand, devices optimized for touch-typing are often too large for comfortable thumb-typing because the size of the keyboards are too large for comfortable hand cradling and thumb reach during thumb-typing. Such devices include mini-laptops, notebooks, or compact laptops. Although these devices are small enough for convenient carrying by the user, the keyboards on these devices are optimized for only touch-typing. Additionally, these keyboards allow for landscape mode typing, normally on a desktop, which presents a physically larger key typing array than the conventional portrait mode typing which is typical of handheld devices designed for thumb-typing. With the mini-laptop keyboard, the user can easily and comfortably enter text using conventional touch-typing. This larger mini-laptop keyboard, however, does not facilitate comfortable and easy thumb-typing because the keys are spaced such that the center keys are too far for the average-person's thumbs to comfortably reach.

While there are compact keyboards having a full standard keyboard layout, this layout is more difficult to use when scaled down to fit onto a smaller device due to the condensed key spacing and physically smaller keys. Thus, there remains a need for a keypad layout that is large enough for comfortable and accurate touch-typing but also small enough for comfortable and accurate thumb-typing when the device is cradled in the user's hands. The result is a need for a reduced key array optimized keyboard that facilitates both handheld thumb-typing and desktop touch-typing.

### BRIEF DESCRIPTION OF THE DRAWINGS

Embodiments of the present disclosure will now be described, by way of example only, with reference to the attached Figures, wherein:

FIG. 1 illustrates an exemplary keyboard optimized for both handheld thumb-typing and touch-typing, but with thumb-typing being shown;

FIG. 2 illustrates the keyboard of FIG. 1 being used for touch-typing;

FIG. 3 illustrates another exemplary keyboard optimized for handheld thumb-typing and touch-typing having a split key layout shown being used for thumb-typing;

FIG. 4 illustrates another exemplary keyboard optimized for handheld thumb-typing and touch-typing including a pair of navigational buttons shown at lower lateral sides of the space bar;

FIG. 5 illustrates an exemplary keyboard optimized for handheld thumb-typing and touch-typing including a trackball assembly shown centered below the space bar;

FIG. 6 illustrates another exemplary embodiment of a keyboard optimized for handheld thumb-typing and touch-typing and having a tapered bottom portion;

FIG. 7A depicts an exemplary embodiment of a handheld device having a keyboard optimized for handheld thumb-typing and touch-typing in an open position;

FIG. 7B shows the exemplary embodiment of FIG. 7A in a closed position;

FIG. 8A depicts an exemplary embodiment of a handheld device having a tapered keyboard optimized for handheld thumb-typing and touch-typing in an open position;

FIG. 8B shows the exemplary embodiment of FIG. 8A in a closed position;

FIG. 8C shows another exemplary embodiment of a device having a keypad that is narrower than the viewing screen;

FIG. 9 depicts another exemplary embodiment of a handheld device having a keyboard including a majority of oval shaped keys and optimized for handheld thumb-typing and touch-typing;

FIG. 10A is a side perspective view of another exemplary embodiment of a handheld device having a keyboard including a pair of grips positioned at an opposite face of the device from the keyboard optimized for handheld thumb-typing and touch-typing;

FIG. 10B is a side perspective view of another exemplary embodiment of a handheld device having a keyboard including a pair of rounded grips positioned at an opposite face of the device from the keyboard optimized for handheld thumb-typing and touch-typing; and

FIG. 10C is a side perspective view of another exemplary embodiment of a handheld device having a keyboard including finger stops indented at an opposite face of the device from the keyboard optimized for handheld thumb-typing and touch-typing.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein.

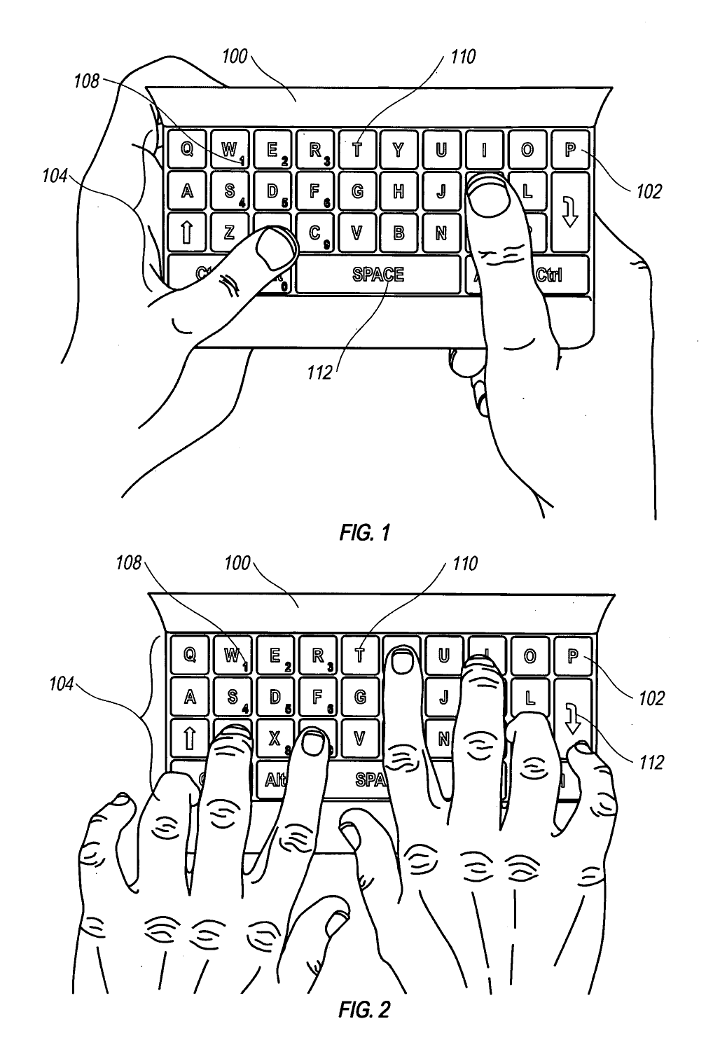

FIGS. 1 and 2 depict a keyboard 100 for a handheld electronic device that is optimized for thumb-typing and conventional touch-typing. The keyboard 100 has a plurality of keys 102. While the keys 102 of the illustrated keyboard 100 are arranged in a grid of a plurality of columns and a plurality of rows, the arrangement of the keys 102 can be in other arrangements as will be described herein. Each key 102 is associated with at least one indicia representing an alphabetic character 110, a numeral 108, or a command 112 (such as a space command, return command, or the like). The plurality of the keys 102 having alphabetic characters 110 are arranged in a standard keyboard layout 104. This standard keyboard layout 104 can be a QWERTY layout (shown), a QZERTY layout, a QWERTZ layout, an AZERTY layout, a Dvorak layout, a Russian keyboard layout, a Chinese keyboard layout, or other similar layout. These standard layouts are provided by way of example and other similar standard layouts are considered within the scope of this disclosure. The keyboard layout 104 can be based on the geographical region in which the handheld device is intended for sale. In some examples, the keyboard can be interchangeable such that the user can switch between layouts.

The plurality of keys 102 having alphabetic characters 110 can also have numeric indicia 108. Such keys 102 can have the numerals 108 arranged in a telephone keyboard layout, such as one according to ITU Standard E.161. In an alternative embodiment, the numerals 108 can be arranged in a calculator-style layout. In yet another alternative embodiment, there can be keys 102 bearing only numerals 108 that are separate from the keys 102 bearing alphabetic characters 110. In a further embodiment, the numerals 108 can be located on the keys 102 of a top row of the keyboard 100.

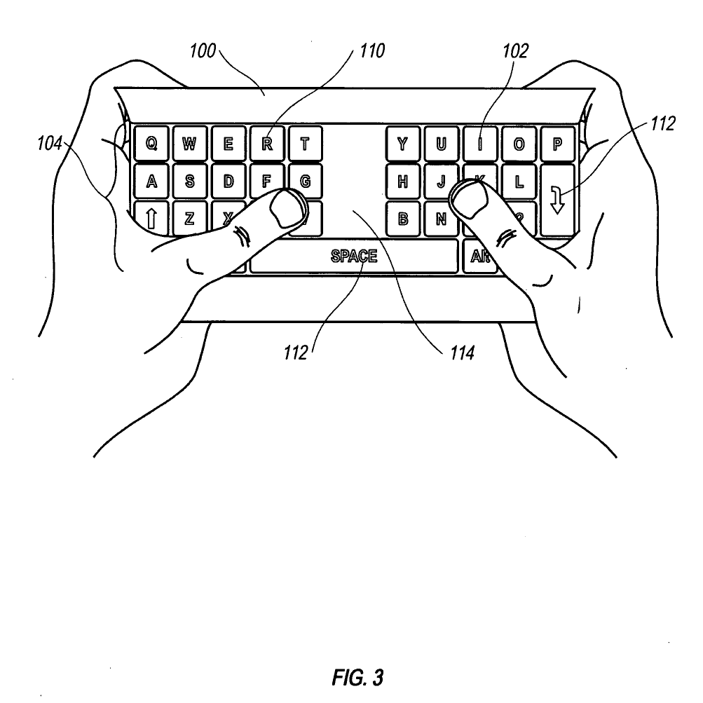

As shown in FIG. 1, the keyboard 100 has dimensions such that a user can cradle the keyboard 100 in his hands and actuate the keys 102 comfortably by thumb-typing. Additionally, and as shown in FIGS. 2 and 3, the keyboard 100 is also dimensioned to allow the user to place the keyboard 100 on a desktop and comfortably actuate the keys 102 by touch-typing or conventional finger typing.

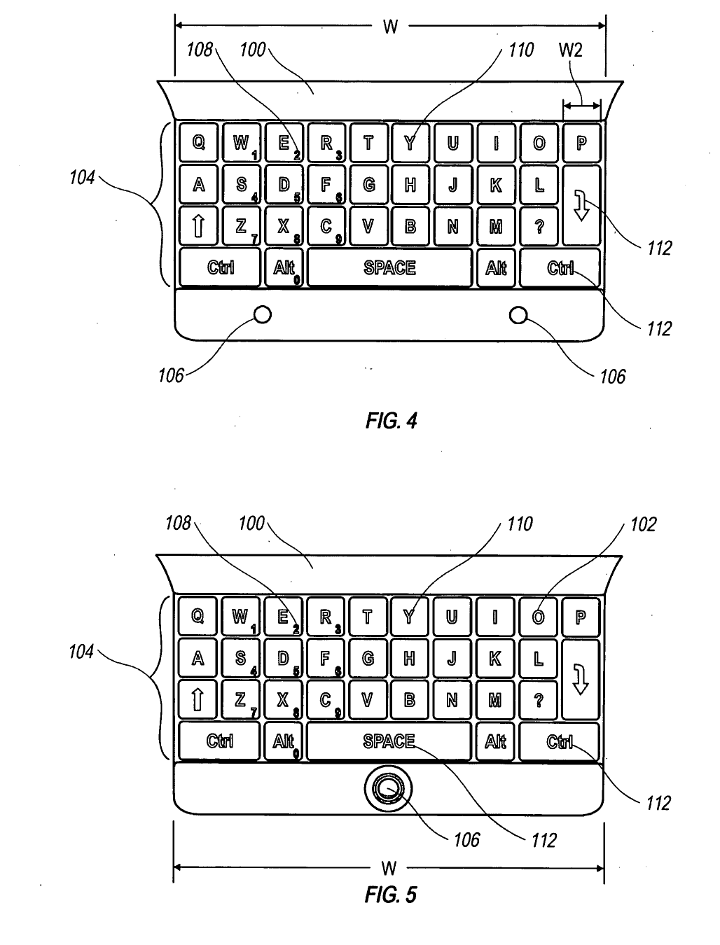

As depicted in FIG. 4, the keyboard 100 is optimized for handheld thumb-typing and desktop touch-typing and has a width (W) that accommodates the hands of a fifty percentile female as well as the hands of a fifty percentile male. Therefore, to accommodate the hands and thumb reach of the average female and male user, an exemplary range of keyboard widths (W) is greater than about 100 millimeters and less than about 160 millimeters.

With such dimensions, the average female or male user can comfortably use the keyboard 100 for thumb-typing when cradling the device in his or her hands and can also comfortably use the keyboard 100 for conventional touch-typing when placing the device on a desktop or other surface. To further facilitate comfortable dual typing methods on the keyboard 100, the individual keys 102 can have a width (W2) that is between approximately eight millimeters to sixteen millimeters. With such widths of the individual keys 102, there is enough space between each key 102 so that when the user touch-types, he does not feel like his hands are cramped and does not worry about inaccurate typing using the keyboard 100. Also, with these individual key widths (W2), the user can cradle the device in his hands and comfortably reach each key 102 using his thumbs without worrying about inaccurately typing text or pressing more than one key 102 with a single thumb engagement.

In these compact electronic devices, the keyboard 100 can have a layout 104 using fewer keys 102 than a conventional desktop or laptop keyboard. Such reduced keyboard layouts 104 can have ten or fewer keys 102 in each row. This arrangement can be such that it forms ten columns of keys 102. In other embodiments, the keys 102 can be positioned such they are not arranged as columns. In other embodiments, the number of keys 102 can vary in the individual rows. While the keys 102 have been described as being arranged in rows, in other embodiments the keys 102 can be arranged in other configurations as well. With a simple layout 104, the keyboard 100 is small enough to be cradled by the user's hands for thumb-typing, but wide enough to be placed on a desktop, a user's lap or other surface for comfortable touch-typing. In other embodiments, more than one alphabetic character can be present on individual keys 102 of the keyboard, 100 thereby further reducing the number of keys 102 required to present a standard layout.

FIG. 3 illustrates an alternative embodiment of the keyboard 100 in which the keyboard 100 is a split keyboard, where the keys 102 are generally divided into halves with a gap-space 114 in between. The gap-space 114 allows the user to more easily actuate the keys 102 on the left-hand side of the gap-space 114 with the left hand and the keys 102 on the right side of the gap-space 114 with the right hand by preventing overlapping of the hands. This can also prevent the user's thumbs from hitting and conflicting with one another, when keys 102 located on opposite sides but adjacent the gap-space 114 are sequentially engaged. For this reason, the gap-space 114 can be advantageously provided with a width that approximates the average user's thumb width and avoids undesirable thumb hits. In at least one embodiment, the gap-space 114 can be about twenty millimeters. The overall width of the keyboard 100 can be approximately one hundred-eighty millimeters in width. The keys 102 on the left-hand side and right-hand side can have the same width, which can be approximately eighty millimeters in width or one side can be larger than the other. While the above examples have been given in relation to the size of the keyboard 100, gap-space, and total width of each side of keys 102 other examples will be known to those of ordinary skill in the art. For example, the left-hand and right-hand side of keys 102 can have a width ranging from about fifty millimeters to about eighty millimeters. The gap-space 114 can have a width ranging from about ten millimeters to about thirty millimeters. Additionally in at least one example, the keyboard 100 comprises virtual keys on a touch-sensitive screen. The width of the gap-space 114 can be user defined in at least one example. In yet a further example, the width of the right-hand side of keys 102 and left-hand side of keys 102 can also be user defined. The respective width of the gap-space 114 can change in response to the adjustment of the width of the right-hand side of keys 102 and left-hand side of keys 102 or the user can be provided with a setting to select which one of the gap-space 114 or the width of the right-hand side of keys 102 and left-hand side of keys 102 should control the overall dimensions of the keyboard 100 displayed on the touch-sensitive screen.

The keyboard 100 can also include a navigational input key 106 for navigating a cursor on a display screen, scrolling through a menu or webpage, or other similar navigational input. As shown in FIG. 4, the navigational input keys 106 are left and right mouse-type buttons. FIG. 5 shows another type of navigational input key 106, a trackball assembly. The navigational input 106 is not limited to these types of navigational input keys but can also be a navigation pad, a multi-directional joystick, direction keys, or the like.

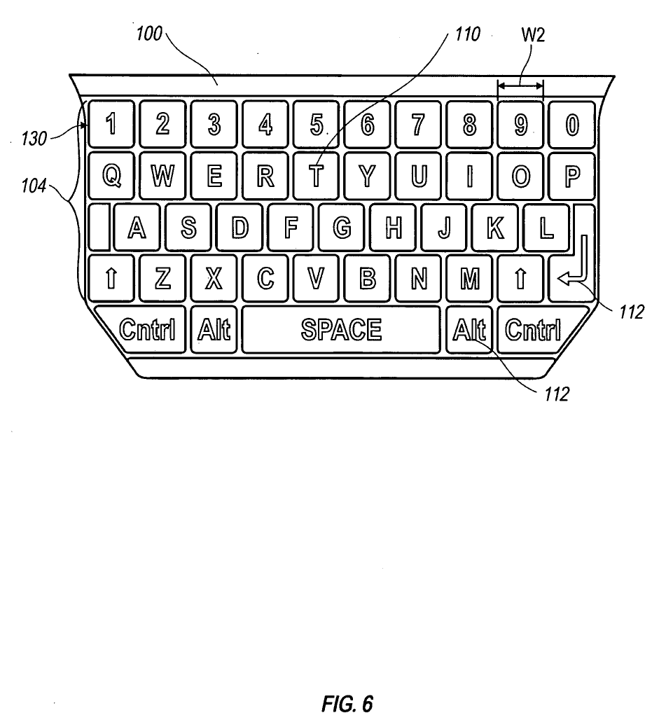

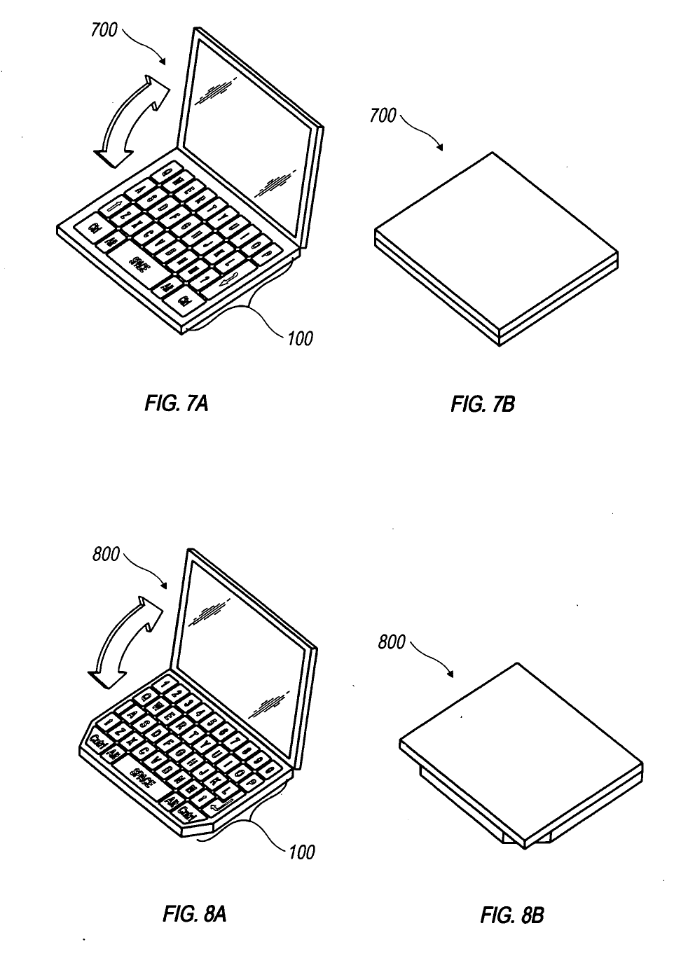

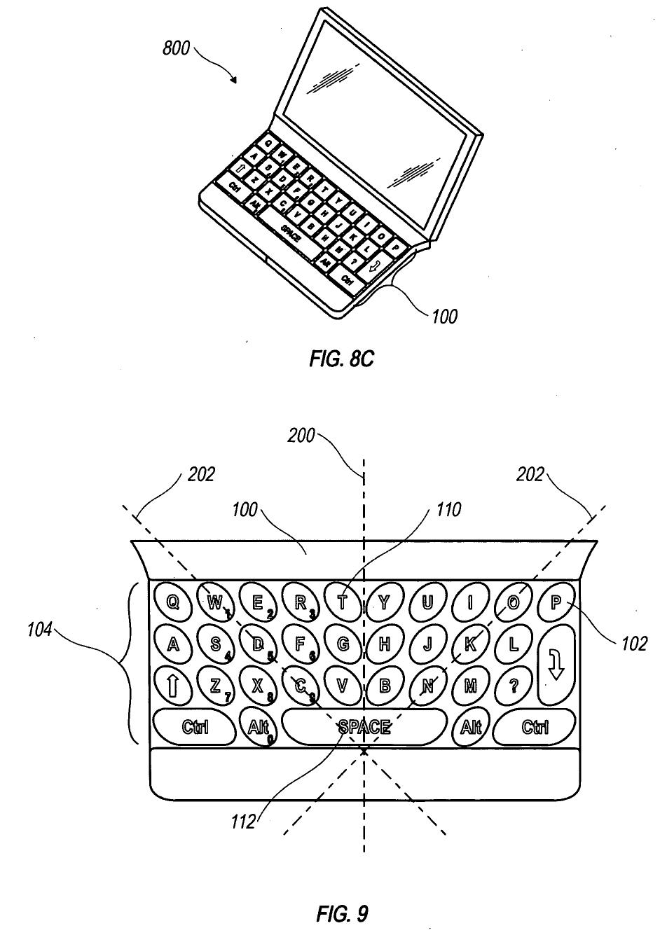

FIG. 6 shows an alternative embodiment of the keyboard 100 where the keyboard 100 is non-rectangular in shape. As depicted, the bottom left and bottom right corners of the keyboard 100 are tapered inwardly. With such tapered corners, the user can easily grip the device when using the keyboard 100 for thumb-typing. The keyboard 100 can also have rounded corners, have tapered lateral sides such that the keyboard 100 is trapezoidal in shape, be circular in shape, or be non-uniform in shape (FIG. 8A-8C). Still referring to FIG. 6, in addition to the rows of keys 102 bearing alphabetic characters 110, the keyboard 100 can have a top row 130 of keys 102 that bear indicia representing function keys, numerals 108, command indicia 112, or the like.

Although it has been described and illustrated herein that the keys 102 are square in shape, they need not be. The keys 102 can also have the shape of a rectangle, a circle, an oval (shown in FIG. 9), a triangle, an oblong figure, or the like. Furthermore, the keys 102 do not need to be arranged in vertically straight columns. Each key 102 has a longitudinal axis 202. The longitudinal axes 202 of the keys 102 to the left of the vertical centerline 200 of the keyboard 100 can be generally parallel with respect to one another. The longitudinal axes of the keys 102 to the right of the vertical centerline 200 of the keyboard 100 can also be generally parallel with respect to one another. As depicted in FIG. 9, the keys 102 are arranged such that they are not in vertically straight columns. Here, the longitudinal axis 202 of each key 102 to the left of the vertical centerline 200 of the keyboard 100 is tilted at a negative acute angle with respect to the vertical centerline 200 of the keyboard 100. Also, the longitudinal axis 202 of each key 102 to the right of the vertical centerline 200 of the keyboard 100 is tilted at a positive acute angle with respect to the vertical centerline 200 of the keyboard 100. This results in an angled key arrangement that facilitates thumb-typing because the keys 102 are arranged along the natural diagonal path a user's thumbs trace during thumb-typing.

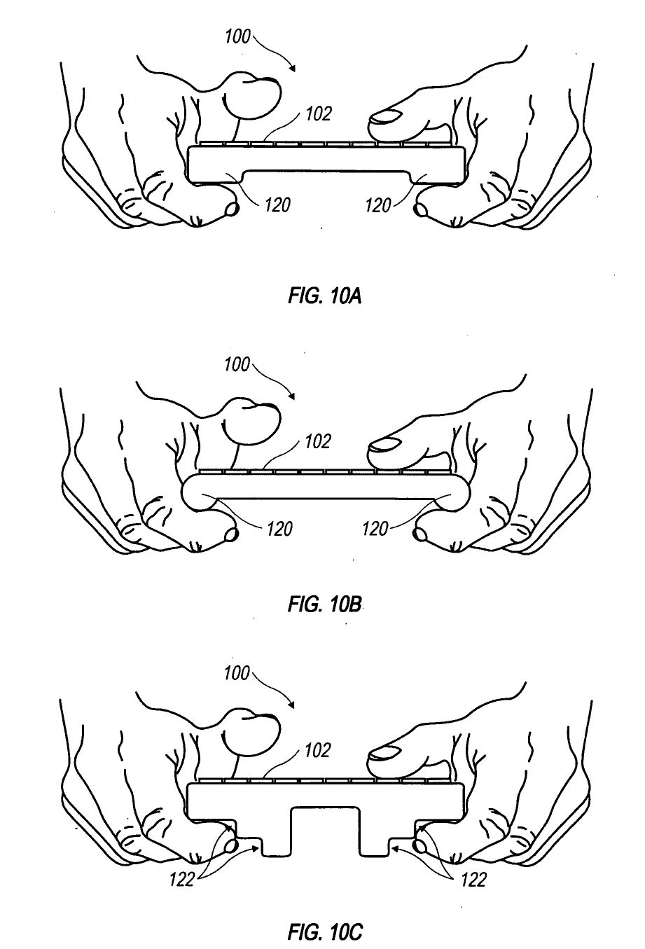

In an alternative embodiment, the keyboard 100 is located at the front face of the device. Additionally, a grip 120 can be attached at the rear face of the device such that it is opposite the keyboard 100 when viewed from the side as shown in FIGS. 10A and 10B. The grip 120 provides wrist support for the user when the device is used for touch-typing and also provides hand support when the device is used for thumb-typing. Also, there can be more than one grip 120 at the rear face of the device. One grip 120 can be placed beneath the keyboard 100 where a user's left hand can grip, and another grip 120 can be placed beneath the keyboard 100 where a user's right hand can grip. These grips 120 can help a user with smaller hands reach distant keys 102. The grips 120 can be rectangular, square, rounded, or another similar shape that facilitates a comfortable and firm grasp on the keyboard 100. Instead of grips 120, indentations can be made at the rear face of the device to act as finger stops 122, as shown in FIG. 10C. Such finger stops 122 can help position the hands for comfortable thumb-typing.

One skilled in the art will appreciate that the optimized keyboard 100 described herein for handheld thumb-typing and desktop typing can be implemented into devices such as mini-laptops, compact laptops, Personal Digital Assistants (PDAs), handheld communication devices, cellphones, and other compact portable devices capable of handheld use. While the above description has at times referenced a physical key or keyboard, it will also be appreciated that the keyboard 100 can have virtual keys, such as a touch-screen keyboard. When the keyboard is comprised of virtual keys, the indicia and size of the keys can be controlled based upon the display of the virtual keys. For instance, the top row of FIG. 6 could be modified depending on whether numeric entry or additional function keys are desired. Additionally, the layout can be changed based upon region or other application based requirements. Additionally, the virtual keyboard layout could be modified by the user in at least one embodiment.

Exemplary embodiments have been described hereinabove regarding the implementation of an optimized keyboard for handheld thumb-typing and desktop typing on a handheld device. Various modifications to and departures from the disclosed embodiments will occur to those having skill in the art. The subject matter that is intended to be within the spirit of this disclosure is set forth in the following claims.

What is claimed is:

1. A handheld device configured for thumb typing and touch typing, comprising:
a body having a front face and a rear face;
a keyboard at the front face of the body comprising a plurality of keys having alphabetic characters associated therewith, said alphabetic characters arranged in one of a QWERTY layout, an AZERTY layout, a QWERTZ layout, QZERTY layout, and a Dvorak layout;
a portion of said plurality of keys also having numerals associated therewith, said numerals arranged in a telephone keypad layout according to ITU Standard E.161;
said keyboard has a width greater than about 100 millimeters and less than about 160 millimeters, and each of said plurality of keys has a width that is approximately 10 millimeters to 16 millimeters;
said plurality of keys having alphabetic characters being arranged such that a first subset of keys of the plurality of keys on the left side of a vertical centerline of the keyboard can be actuated with a left thumb when the device is held by a user without repositioning cradling hands of the user and a second subset of keys of the plurality of keys on the right side of the vertical centerline of the keyboard can be actuated with a right thumb when the device is held by a user without repositioning the cradling hands of the user; and
said plurality of keys also being positioned such that when the hands of the user are placed on top of the plurality of keys, said keys having alphabetic characters can be actuated by the digits of the user without substantially repositioning of hands of the user from a resting position on top of the plurality of keys.

2. The handheld device of claim 1, wherein the keyboard is a split keyboard having the plurality of keys with a gap-space between the first subset of keys and the second subset of keys.

3. The handheld device of claim 1, further comprising a navigational input key.

4. The handheld device of claim 3, wherein the navigational input key is one of a trackball assembly, a navigational touchpad, a multi-directional joystick, and navigational buttons.

5. The handheld device of claim 1, wherein the keyboard has a non-rectangular shape.

6. The handheld device of claim 1, wherein the plurality of keys are arranged in a grid having a plurality of rows and a plurality of columns, each of said plurality of rows having ten or fewer keys.

7. The handheld device of claim 1, further comprising a grip at the rear face of the body such that the grip is positioned opposite the keyboard when the device is held upright.

8. The handheld device of claim 1, wherein:
each key of the first subset of keys has a longitudinal axis, said longitudinal axis tilted at a negative acute angle with respect to the vertical centerline of the keyboard; and
each key of the second subset of keys has a longitudinal axis, said longitudinal axis tilted at a positive acute angle with respect to the vertical centerline of the keyboard.

9. The handheld device of claim 1, wherein each of said plurality of keys has a height that is approximately 10 millimeters to 16 millimeters.

10. The handheld device of claim 1, wherein the keyboard is provided on a touch-sensitive display screen.

11. The handheld device of claim 11, wherein the keyboard is a split keyboard having the plurality of keys with a gap-space between the first subset of keys and the second subset of keys, said gap-space being user defined.

12. A keyboard arrangement for a handheld device comprising:
a plurality of keys having alphabetic characters associated therewith, said alphabetic characters arranged in one of a QWERTY layout, an AZERTY layout, a QWERTZ layout, QZERTY layout, and a Dvorak layout;
a portion of said plurality of keys also having numerals associated therewith, said numerals arranged in a telephone keypad layout according to ITU Standard E.161;
said keyboard has a width greater than about 100 millimeters and less than about 160 millimeters, and each of said plurality of keys has a width that is approximately 10 millimeters to 16 millimeters;
said plurality of keys having alphabetic characters being arranged such that a first subset of keys of the plurality of keys on the left side of a vertical centerline of the keyboard can be actuated with a left thumb when the device is held by a user without repositioning cradling hands of the user and a second subset of keys of the plurality of keys on the right side of the vertical centerline of the keyboard can be actuated with a right thumb when the device is held by a user without repositioning the cradling hands of the user; and
said plurality of keys also being positioned such that when the hands of the user are placed on top of the plurality of keys, said keys having alphabetic characters can be actuated by the digits of the user without substantially repositioning of hands of the user from a resting position on top of the plurality of keys.
